(19) United States
(12) Patent Application Publication
(10) Pub. No.: US 2025/0273441 A1
(43) Pub. Date: Aug. 28, 2025

(54) LIQUID-COOLED OPTICAL WINDOW FOR SEMICONDUCTOR PROCESSING CHAMBER

(71) Applicant: Lam Research Corporation, Fremont, CA (US)

(72) Inventors: David S. L. Mui, Fremont, CA (US); Songqi Gao, Sunnyvale, CA (US); Bryan Michael Cord, San Jose, CA (US); Ilia Kalinovski, Berkeley, CA (US); Butch Berney, Pleasanton, CA (US); Himanshu Chokshi, Fremont, CA (US); Mark Naoshi Kawaguchi, San Carlos, CA (US)

(21) Appl. No.: 18/857,440

(22) PCT Filed: Apr. 14, 2023
(86) PCT No.: PCT/US2023/065807

§ 371 Date: Oct. 16, 2024

Related U.S. Application Data
(60) Provisional application No. 63/332,562, filed on Apr. 19, 2022.

(51) Int. Cl. H01J 37/32; H01L 21/687

(52) U.S. Cl. CPC H01J 37/32522; H01L 21/68785; H01J 2237/002; H01J 2237/2445; H01J 2237/24585; H01J 2237/334

(57) ABSTRACT

Window/cooling plate assemblies for use with illumination-based radiative heating systems for semiconductor wafer processing tools are provided. Such assemblies may have a window and a cooling plate that are placed adjacent each other; one or more cooling passages may be located within one or both of the window and the cooling plate. The window and cooling plate may be optically transparent to at least some visible light and the window additionally optically transparent to at least some infrared light.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

In some semiconductor processing tools, wafers may be supported by a pedestal having a transparent upper surface and a large number of light sources, e.g., LEDs, located within the pedestal. Such arrangements may allow for rapid heating and cooling of the wafers using, for example, radiative heating using visible light. Examples of such pedestals are detailed, for example, in WO 2021202171.

Discussed herein are enhancements to pedestal systems having light-based heating systems incorporated therein.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a window having a first surface and a second surface, a cooling plate having a third surface and a fourth surface, and one or more cooling passages interposed between the first surface and the fourth surface. The first surface may be non-reactive with hydrogen fluoride and the window and cooling plate may both be transparent to at least some light in the 400 nm to 800 nm spectrum within at least a first cylindrical zone having a center axis perpendicular to the first surface. The one or more cooling passages may be at least partially within the first cylindrical zone, and the third surface may be adjacent to the second surface.

In some such implementations, the third surface may be bonded to the second surface. In some additional or alternative such implementations, at least one of the one or more cooling passages may be provided, at least in part, by an open channel in the third surface that is capped by the second surface.

In some implementations, at least one of the one or more cooling passages may be provided, at least in part, by an open channel in the second surface that is capped by the third surface.

In some implementations, at least one of the one or more cooling passages may be located between the fourth surface and the second surface. In some such implementations, the cooling plate may include a first portion and a second portion, the first portion may include the third surface and a fifth surface, the second portion may include the fourth surface and a sixth surface, the fifth surface may be bonded to the sixth surface, and each of the one or more cooling passages may be an open channel in one or both of the fifth surface and the sixth surface.

In some implementations, portions of at least a first cooling passage of the one or more cooling passages may be distributed throughout at least an annular sub-portion of the first cylindrical zone.

In some such implementations, at least the first cooling passage of the one or more cooling passages may include a first segment that lies entirely within a circular sector zone and that extends from one radial edge of the circular sector zone to another radial edge of the circular sector zone, the circular sector zone may have an angle of at least 1500 and an outer radius less than twice the average width of the first cooling passage within the circular sector zone, the first cooling passage may have a second segment of equal or lesser length than the first segment, the first segment may transition to the second segment, and at least one of the first segment and the second segment may have a minimum cross-sectional area that is smaller than an average cross-sectional area of the first segment.

In some such implementations, the minimum cross-sectional area may be at least 10% smaller than the average cross-sectional area of the first segment. In some implementations, the minimum cross-sectional area may be between 10% and 20% smaller than the average cross-sectional area of the first segment.

In some such implementations, the minimum cross-sectional area may be in the second segment and may be fluidically interposed between the first segment and a first outlet of the first cooling passage.

In some implementations, the first cooling passage may lead from a first inlet to the first outlet, a first portion of the first cooling passage may be fluidically interposed between the first inlet and a second portion of the first cooling passage, the second portion of the first cooling passage may be fluidically interposed between the first portion of the first cooling passage and the first outlet, and the first portion of the first cooling passage and the second portion of the first cooling passage may follow nested, generally spiral-shaped paths.

In some implementations, the first cooling passage may lead from a first inlet to a first outlet, a first portion of the first cooling passage may be fluidically interposed between the first inlet and a second portion of the first cooling passage, the second portion of the first cooling passage may be fluidically interposed between the first portion of the first cooling passage and the first outlet, and the first portion of the first cooling passage and the second portion of the first cooling passage may follow nested, generally spiral-shaped paths.

In some implementations, the apparatus may further include a pump having a pump inlet and a pump outlet. The pump inlet may be fluidically connected with the first outlet such that suction developed at the pump inlet also generates suction at the first inlet, and the pump outlet may not be connected with the first inlet so that positive pressure developed at the pump outlet is not communicated to the first inlet.

In some implementations, the one or more cooling passages may not pass through a cylindrical center zone centered on the center axis and extending through the window and the cooling plate.

In some implementations, the cylindrical center zone may have a radius of at least 5 mm. In some such implementations, the radius of the cylindrical center zone may be less than 15 mm. In some additional or alternative such implementations, the cooling plate may have a hole in it within the cylindrical center zone.

In some implementations, the apparatus may further include an optical sensor configured to obtain temperature measurements through the window and the cooling plate and within the cylindrical center zone. In some such implementations, the optical sensor may be a pyrometer.

In some implementations, the cylindrical center zone may have a radius of at least 75 mm.

In some implementations, the apparatus may further include a plurality of illumination devices located within the first cylindrical zone and positioned so as to emit light, responsive to being powered, through the cooling plate and the window.

In some such implementations, the illumination devices may be light-emitting diodes.

In some such implementations, there may be 1500 or more illumination devices located within the first cylindrical zone. In some alternative or additional such implementations, the illumination devices may be configured to, in aggregate, emit at least 0.1 kW of radiant energy when at full power.

In some implementations, the illumination devices may be configured to emit light predominantly in the 350 nm to 950 nm wavelength range.

In some implementations, the apparatus may further include a pedestal housing. The pedestal housing may include an internal cavity, the window may be installed in the pedestal housing so as to close off the internal cavity, and the illumination devices may be located within the internal cavity.

In some implementations, the apparatus may further include a plurality of wafer supports. Each wafer support may have a first portion that lies within a second cylindrical zone and a second portion that lies outside of the second cylindrical zone, the first portion of each wafer support may have a wafer contact surface that is spaced apart from the first surface by a first distance, the first distance may be a non-zero distance, and the second portion of each wafer support may support the first portion of that wafer support relative to the pedestal housing.

In some such implementations, there may be three wafer supports.

In some implementations, the diameter of the first cylindrical zone may be larger than the diameter of the second cylindrical zone.

In some implementations, the first cylindrical zone may have a diameter of 300 mm or larger.

In some implementations, the apparatus may further include a pump having a pump inlet and a pump outlet. At least a first cooling passage of the one or more cooling passages may have a first inlet and a first outlet, with the first cooling passage fluidically interposed between the first inlet and the first outlet. The pump inlet may be fluidically connected with the first outlet such that suction developed at the pump inlet also generates suction at the first inlet, and the pump outlet may not be connected with the first inlet so that positive pressure developed at the pump outlet is not communicated to the first inlet.

In some implementations, the window may be made, at least in part, of mono-crystalline aluminum oxide (sapphire), aluminum oxynitride (ALON), or magnesium aluminate (spinel).

In some additional or alternative such implementations, the cooling plate may be made, at least in part, of mono-crystalline aluminum oxide (sapphire), aluminum oxynitride (ALON), magnesium aluminate (spinel), or silicon dioxide (quartz).

In some implementations, the one or more cooling passages may include only a single cooling passage.

In some of the implementations, the window and cooling plate may both be at least 80% transmissive to at least some light in the 400 nm to 800 nm wavelength spectrum to a depth of at least 2 mm within at least the first cylindrical zone. In some further such implementations, the window and cooling plate may both be at least 80% transmissive to all light in the 400 nm to 800 nm wavelength spectrum to a depth of at least 2 mm within at least the first cylindrical zone.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts an example pedestal having an illumination-based heating system.

FIG. 2 depicts the same pedestal as in FIG. 1, but with a wafer being supported by wafer supports thereof over a window thereof.

FIG. 3 depicts a section view of the pedestal of FIG. 2.

FIG. 4 depicts an exploded view of the pedestal of FIGS. 1 and 2.

FIG. 5 depicts a view of a window/cooling plate assembly on the left and the same assembly in an exploded view on the right.

FIG. 6 depicts a plan view of the window/cooling plate assembly of FIG. 5.

FIGS. 7 and 8 depict cross-sections through the section lines shown in FIG. 6.

FIG. 9 depicts an alternate implementation of a window and a cooling plate.

FIG. 10 depicts another alternate implementation of a window and a cooling plate.

FIG. 11 depicts another alternate implementation of a window and a cooling plate.

FIG. 12 depicts another alternate implementation of a window and a cooling plate.

FIG. 13 depicts a schematic of a semiconductor processing chamber in which a pedestal such as the pedestals discussed herein may be used.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Introduction and Context

Semiconductor fabrication processes often involve patterning and etching of various materials, including conductors, semiconductors, and dielectrics. Some examples include conductors, such as metals or carbon; semiconductors, such as silicon or germanium; and dielectrics, such as silicon oxide, aluminum dioxide, zirconium dioxide, hafnium dioxide, silicon nitride, and titanium nitride. Atomic layer etching (“ALE”) processes provide one class of etching techniques that involve repeated variations in etch conditions over the course of an etch operation. ALE processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts. Generally, a cycle contains one instance of a unique sequence of operations.

As an example, a conventional ALE cycle may include the following operations: (i) delivery of a reactant gas to perform a modification operation, (ii) purging of the reactant gas from the chamber, (iii) delivery of a removal gas and an optional plasma to perform a removal operation, and (iv) purging of the chamber. In some embodiments, etching may be performed nonconformally. The modification operation generally forms a thin, reactive surface layer with a thickness less than the un-modified material. In an example modification operation, a substrate may be chlorinated by introducing chlorine into the chamber. Chlorine is used as an example etchant species or etching gas, but it will be understood that a different etching gas may be introduced into the chamber. The etching gas may be selected depending on the type and chemistry of the substrate to be etched. A plasma may be ignited and chlorine reacts with the substrate for the etching process; the chlorine may react with the substrate or may be adsorbed onto the surface of the substrate. The species generated from a chlorine plasma can be generated directly by forming a plasma in the process chamber housing the substrate or they can be generated remotely in a process chamber that does not house the substrate, and can be supplied into the process chamber housing the substrate.

In some instances, a purge may be performed after a modification operation. In a purge operation, non-surface-bound active chlorine species may be removed from the process chamber. This can be done by purging and/or evacuating the process chamber to remove the active species, without removing the adsorbed layer. The species generated in a chlorine plasma can be removed by simply stopping the plasma and allowing the remaining species decay, optionally combined with purging and/or evacuation of the chamber. Purging can be done using any inert gas such as N2, Ar, Ne, He and their combinations.

In a removal operation, the substrate may be exposed to an energy source to etch the substrate by directional sputtering (this may include activating or sputtering gas or chemically reactive species that induce removal). In some embodiments, the removal operation may be performed by ion bombardment using argon or helium ions. During removal, a bias may be optionally turned on to facilitate directional sputtering. In some embodiments, ALE may be isotropic; in some other embodiments ALE is not isotropic when ions are used in the removal process.

In various examples, the modification and removal operations may be repeated in cycles, such as about 1 to about 30 cycles, or about 1 to about 20 cycles. Any suitable number of ALE cycles may be included to etch a desired amount of film. In some embodiments, ALE is performed in cycles to etch about 1 Å to about 50 Å of the surface of the layers on the substrate. In some embodiments, cycles of ALE etch between about 2 Å and about 50 Å of the surface of the layers on the substrate. In some embodiments, each ALE cycle may etch at least about 0.1 Å, 0.5 Å, or 1 Å.

In some instances, prior to etching, the substrate may include a blanket layer of material, such as silicon or germanium. The substrate may include a patterned mask layer previously deposited and patterned on the substrate. For example, a mask layer may be deposited and patterned on a substrate including a blanket amorphous silicon layer. The layers on the substrate may also be patterned. Substrates may have “features” such as fins, or holes, which may be characterized by one or more of narrow and/or re-entrant openings, constrictions within the feature, and high aspect ratios. One example of a feature is a hole or via in a semiconductor substrate or a layer on the substrate. Another example is a trench in a substrate or layer. In various instances, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

The use of plasma during conventional etching presents numerous challenges and disadvantages. For instance, it is generally desirable to create the same plasma conditions for each ALE cycle of a single substrate as well as for all substrates in a batch, but it can be difficult to repeatedly recreate the same plasma conditions due to some plasmas changing due to accumulation of material in the process chamber. Additionally, many conventional ALE processes may cause damage to exposed components of the substrate, such as silicon oxide, may cause defects, and may increase the top-to-bottom ratio of a pattern and increase the pattern loading. Defects may lead to pattern-missing to the extent that the device may be rendered useless. Plasma-assisted ALE also utilizes small radicals, i.e., deeply dissociated radicals, that are more aggressive which causes them to remove more material than may be desired, thereby reducing the selectivity of this etching. As a result, conventional ALE techniques are often unsuitable for selectively etching some materials, such as aluminum dioxide, zirconium dioxide, hafnium dioxide, silicon nitride, and titanium nitride. However, apparatuses that do not use a plasma and that are able to provide rapid and precise temperature control of a substrate during processing may allow some or all of these materials to be etched.

### Apparatuses for Thermal Processing

By rapidly and precisely controlling a substrate's temperature during semiconductor processing, it is possible to perform etching using thermal energy, rather than or in addition to plasma energy, to drive the modification and removal operations. In certain embodiments, etching that relies upon chemical reactions in conjunction with primarily thermal energy, not a plasma, to drive the chemical reactions in the modification and removal operations may be considered “thermal etching”. This etching is not limited to ALE; it is applicable to any etching technique.

In certain embodiments, thermal etching processes, such as those employing one or more thermal cycles, have relatively fast heating and cooling and relatively precise temperature control. In some cases, these features may be leveraged to provide good throughput and/or to reduce nonuniformity and/or wafer defects.

However, many conventional etching apparatuses do not have the ability to adjust and control the temperature of the substrate with adequate speed. For example, while some etching apparatuses may be able to heat a substrate to multiple temperatures, they can do so only slowly, or they may not be able to reach the desired temperature ranges, or they may not be able to maintain the substrate temperature for the desired time and at the desired temperature ranges. Similarly, typical etching apparatuses are often unable to cool the substrate fast enough to enable high throughput or cool the substrate to the desired temperature ranges. For some applications, it is desirable to reduce the temperature ramp times as much as possible, such as to less than about 120 seconds in some embodiments, but many conventional etching apparatuses with resistive heaters in the pedestal cannot heat, cool, or both, a substrate in less than that time; it may take some apparatuses multiple minutes to cool and/or heat a substrate, which slows throughput.

As detailed in WO 2021202171, by including a large number of illumination devices, e.g., light-emitting diodes (LEDs), in the interior of a pedestal and configuring such illumination devices to emit light upward out of the pedestal (and through a window located in the top of the pedestal), it is possible to use such illumination to heat silicon wafers. For example, in some implementations discussed herein, such illumination devices may be configured to, when powered and in aggregate, emit at least 0.1 kW of radiant energy and/or light that is predominantly in the 350 nm to 950 nm wavelength range.

For example, silicon wafers may be generally opaque to visible light but transparent to infrared light (at least, at temperatures below 400° C.). This allows illumination devices that emit visible light, e.g., white light LEDs, to be used to provide radiative energy to a silicon wafer that may then be absorbed by the silicon wafer, radiatively heating the silicon wafer. At the same time, such illumination devices may be protected behind, for example, a quartz or sapphire window to protect the illumination devices from exposure to the processing gases that may be used within the semiconductor processing chamber housing the silicon wafer. As the quartz and sapphire windows are generally optically transparent to visible light, very little of the radiant energy from the illumination devices may be lost transiting the window, thereby resulting in the emitted radiant energy being directed to the silicon wafer with high efficiency.

The present inventors, however, identified several issues that such systems may encounter, however. For example, such illumination-based heating systems may, in some cases, be used to heat silicon wafers to extremely high temperatures, e.g., ˜400° C. A silicon wafer that is generally thermally isolated, e.g., supported through only minimal contact with a supporting structure and located within a vacuum environment such that radiative heat transfer mechanisms are completely dominant over conductive and convective heat transfer mechanisms, will tend to shed heat primarily through black-body radiation, which is primarily in the infrared spectrum.

The inventors realized that heat from such high-temperature wafers was being emitted in the form of infrared radiation back at the windows that were interposed between the silicon wafers and the illumination devices. When those windows were made of quartz, a thermal feedback loop would develop in which infrared heat emitted as blackbody radiation from the silicon wafer would, in turn, strike the quartz window and be absorbed by the quartz material due to quartz's poor transmissivity of infrared wavelength light. This, in turn, caused the quartz window to increase in temperature and consequently resulted in blackbody radiation from the quartz window being emitted back towards the silicon wafer, resulting in secondary heating of the silicon wafer.

Moreover, the quartz window tended to exhibit a noted thermal gradient due to its relatively poor thermal conductivity. For example, the quartz windows in question were generally circular and generally the same size as, or large than, the diameter of the silicon wafer. Such windows are supported about their periphery, providing a thermally conductive contact path from the edge of such a window into the pedestal housing the illumination devices. This, however, leads to such quartz windows exhibiting a significant center-to-edge temperature gradient, e.g., +250° C. near the center of the window and ˜50° C. near the edges. This temperature gradient, in turn, causes the blackbody radiation that is emitted from the window towards the silicon wafer to exhibit a similar gradient, resulting in non-uniform blackbody heating of the silicon wafer by the quartz window. This causes the silicon wafer to exhibit non-uniform processing, resulting in wafer non-uniformity.

The present inventors determined that the issues associated with blackbody radiation from the quartz window could potentially be alleviated by using a material such as sapphire (monocrystalline aluminum dioxide, Al₂O₃), AlON™ (aluminum oxynitride, (AlN)ₓ(Al₂O₃)₁₋ₓ), or Magnesium Aluminate Spinel™ (also simply called Spinel™, referring to magnesium aluminate, MgAl₂O₄) for the window. Such materials are optically transmissive (e.g., ≥80% transmissivity at 2 mm material depth) to at least some (or all) light in the visible light spectrum (e.g., 400 nm to 800 nm) and also to at least some light in the infrared spectrum (optically transmissive, in this context, referring to the amount of optical transmission that occurs for light that actually enters the material as opposed to being reflected off an exterior surface-if, for example, 30% of the light that strikes a given material is reflected off of the material but 80% of the remaining 70% of the light that enters the material passes through the material to a depth of at least 2 mm, then that material would still be viewed as being “optically transmissive” to such light-however, it will be understood that in order for the windows and cooling plates discussed herein to be effective, care should be taken to avoid an undesirable amount of reflectance, as this may cause heating of the light sources and may reduce the efficiency of the heating system for the purposes of wafer heating). For example, sapphire, AlON™, and Spinel™ all have optical transmittance of 80% or higher at 2 mm of material depth in the 500 nm to 4000 nm wavelength range. Near-infrared radiation, for example, has a wavelength range of 750 nm to 1400 nm, and short-wavelength infrared has a wavelength range of 1400 nm to 3000 nm, so such materials would generally be optically transparent to much of the blackbody radiation emitted by an elevated-temperature silicon wafer, e.g., a silicon wafer that is at 200° C., 300° C., or 400° C. As a result, a window made of such a material will absorb much less heat from blackbody radiation from the elevated-temperature silicon wafer as would be absorbed by an equivalently sized quartz window.

Moreover, materials such as sapphire, AlON™, and Spinel™ all exhibit much greater thermal conductivity compared to quartz, e.g., sapphire at 40 W/m-C°@25° C., AlON™ at 12.3 W/m-C°@23° C., and Spinel™ at 25 W/m-C°@25° C. as compared with quartz at 1.4 W/m-C°@25° C. Put another way, the thermal conductivity of materials such as sapphire, AlON™, and Spinel™ is at least an order of magnitude higher than that of quartz.

As a result, whatever heat is absorbed by such a window will flow much more rapidly to lower-temperature regions of the window, resulting in a much less pronounced temperature gradient within such a window. Consequently, whatever blackbody radiation is emitted from such a window will generally be significantly less than the blackbody radiation that would be emitted from an equivalent quartz window and will also be much more uniform with respect to center-to-edge temperature variation (and thus the blackbody radiation emitted thereby towards the silicon wafer will also tend to be much more uniform).

Materials such as sapphire, AlON™, and Spine™ are also highly resistant, if not immune, to attack from at least some species of gas commonly used in semiconductor processing operations. For example, sapphire, AlON™, and Spinel™ are all non-reactive with hydrogen fluoride gas, which is commonly used in semiconductor processing operations. AlON™ and sapphire, for example, are effectively impervious to hydrogen fluoride vapor, a highly corrosive gas commonly used in semiconductor processing operations.

Materials such as sapphire, AlON™, and Spinel™ may also exhibit a higher flexural strength than other optically transparent materials, thereby allowing the thickness of windows made with such materials to be reduced as compared with other optically transparent materials while still allowing a vacuum environment to be provided on one side of such windows and atmospheric pressure on the other (or on the the cooling plate backing the window). Such windows may be, for example, on the order of 300 mm to 400 mm in diameter, e.g., approximately 300 mm, 310 mm, 320 mm, 330 mm, 340 mm, 350 mm, 360 mm, 370 mm, 380 mm, 390 mm, or 400 mm in diameter, and on the order of 2 mm to 15 mm thick, e.g., about 2 mm, 3 mm, 4 mm, 5 mm, 6 mm, 7 mm, 8 mm, 9 mm, 10 mm, 11 mm, 12 mm, 13 mm, 14 mm, or 15 mm thick, in some implementations.

It will be understood that in addition to materials such as sapphire, AlON™, or Spinel™, other materials, e.g., monocrystalline calcium fluoride, may be used for the window as well if they offer optical transmissivity, thermal conductivity, and chemical inertness properties similar to those discussed above.

The use of a sapphire, AlON™, or Spinel™ window may thus generally eliminate, or at least mitigate to an acceptable level, the issues discussed above with respect to the use of quartz windows in heating silicon wafers to certain temperatures and under certain conditions.

Additionally, there may be issues with such windows emitting some blackbody radiation and, potentially, with temperature gradient effects. The magnitude of such issues may be reduced from the levels that are seen with quartz windows, but may still be undesirably high under some processing conditions. Moreover, if the window is made of a material such as sapphire, AlON™, or Spinel™, most of the blackbody radiation from the silicon wafer may be transmitted through the window and onto the illumination devices instead of being absorbed by the window (as it would be if the window were quartz). This may cause damage to the illumination devices and/or the substrate on which they may be mounted.

The present inventors determined that the capabilities of a sapphire, AlON™, or Spinel™ window could be extended through coupling of such a window with a liquid cooling system. For example, such a window could be coupled with a cooling plate that was made of a material having similar optical transmissivity to at least some, or all, light in the visible spectrum of light as the window. The cooling plate and the window, in aggregate, would have one or more cooling passages through which a coolant, e.g., water, deionized water, distilled water, or other suitable liquid coolant may be flowed.

While the window may be made of a material such as sapphire, AlON™, or Spinel™, the cooling plate may be made of a similar material or, for example, quartz. As the cooling plate and the window may be actively cooled by flowing liquid coolant through the one or more cooling passages, the extra heat that is absorbed by such a cooling plate may be flushed away by the circulating coolant, resulting in the temperature of the cooling plate being kept at an acceptable level, e.g., less than 90° C. or less than 50° C., despite being made of quartz. Additionally, any center-to-edge temperature variation in the cooling plate may be mitigated by the cooling provided by the cooling passages. Whatever temperature variation may exist in the cooling plate may be further mitigated by the window prior to affecting the silicon wafer. For example, a prototype window/cooling plate in which the window was made of monocrystalline sapphire and the cooling plate made of quartz was tested under conditions in which wafers heated by the illumination devices within the pedestal having the window/cooling plate were cycled between 120° C. to 400° C. During such testing, the window exhibited center/mid/edge temperatures that were all within ˜10° C. of each other when the silicon wafer was at 400° C. and within ˜2° C. of each other when the silicon wafer was at 120° C.; the window generally stayed at a temperature between 30° C. and 50° C. during such testing. This is a dramatic improvement over the nearly 200° C. temperature variation, and peak window temperature at the window center of +250° C., that was seen with a quartz window in testing.

The above concepts may, for example, be implemented in practice in a variety of ways. The following Figures provide insight as to several representative implementations of such concepts.

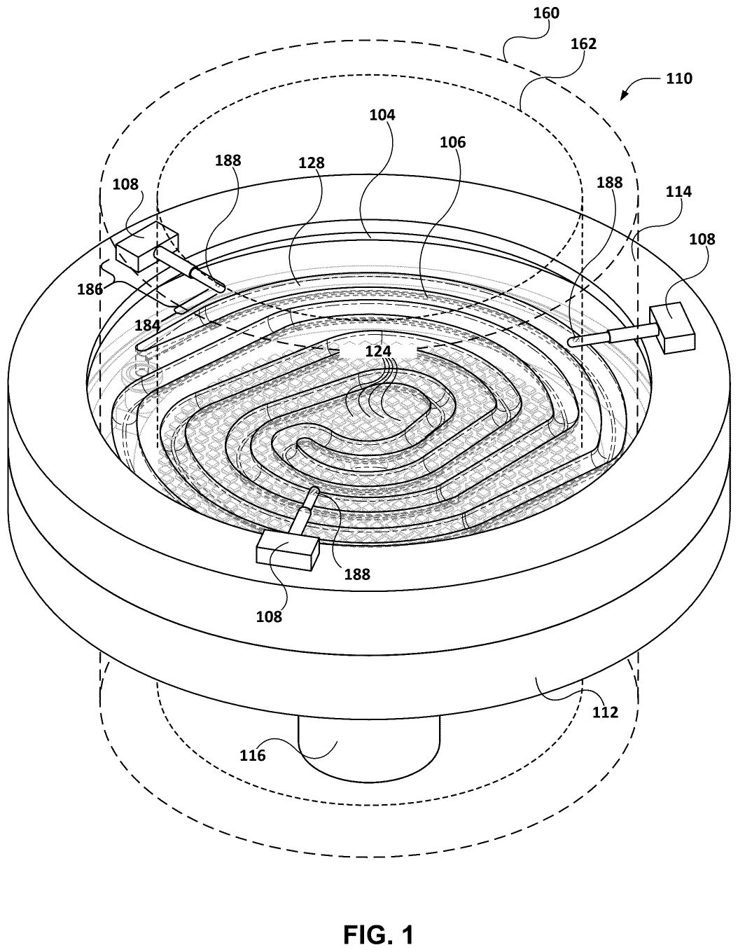

FIG. 1 depicts an example pedestal having an illumination-based heating system. In FIG. 1, pedestal 110 is depicted which has a pedestal housing 112 supported by a stem 116. The pedestal housing 112 may contain within it a plurality of illumination devices 124, e.g., LEDs, that are configured to emit light upwards, through a window 104 and a cooling plate 106. The cooling plate 106 and the window 104 may be held in place relative to the pedestal housing 112 by a collar 114 or other structure.

The cooling plate 106 and the window 104 may, between them, include one or more cooling passages 128 that may be used to circulate a liquid coolant. One or more portions of the one or more cooling passages may pass through a first cylindrical zone 160, thereby allowing the portions of the window 104 and the cooling plate 106 within the first cylindrical zone 160 to be actively cooled by the liquid coolant. The window 104 and the cooling plate 106 may be optically transparent within the first cylindrical zone 160, i.e., at least 80% transmissive to at least some light in the 400 nm to 800 nm spectrum to a depth of at least 2 mm. In some implementations, the window 104 and the cooling plate 106 may be at least 80% transmissive to all light in the 400 nm to 800 nm spectrum to a depth of at least 2 mm within at least the first cylindrical zone. In some additional implementations, at least the window 104 may also be optically transparent to infrared light in the 750 nm to 1400 nm wavelength range. For example, the window 104 may be made of a material such as monocrystalline sapphire, AlON™ or Spinel™. In some implementations, the window 104 and the cooling plate 106 may be at least 80% transmissive to at least some (or all) light in the 400 nm to 800 nm spectrum to a depth of at least 2 mm across all or substantially all, e.g., at least 90%, of the portions of the window 104 and the cooling plate 106 that lie within the first cylindrical zone.

A plurality of, e.g., three, wafer supports 108 may be provided at locations around the window 104 such that inwardly extending members of the wafer supports may overlap with a wafer that may be placed thereupon, thereby supporting the wafer from below and holding the wafer aloft above the window 104 by a first, non-zero distance. For example, each wafer support 108 may have a first portion 184 with a wafer contact surface 188, as well as a second portion 186 that supports the first portion 184 relative to the remainder of the pedestal 110. The first portions 184 and the wafer contact surfaces 188 may, for example, lie within a second cylindrical zone 162, e.g., that may be sized to have the same diameter as a wafer that is to be processed using the pedestal 110. The first cylindrical zone 160 and the second cylindrical zone 162 may, for example, be centered on center axis 158. In some implementations, the first cylindrical zone 160 may be larger than (or the same size as) the second cylindrical zone 162. For example, the first cylindrical zone 160 may have a diameter that is greater than or equal to the diameter of the wafer 102, e.g., greater than or equal to 300 mm.

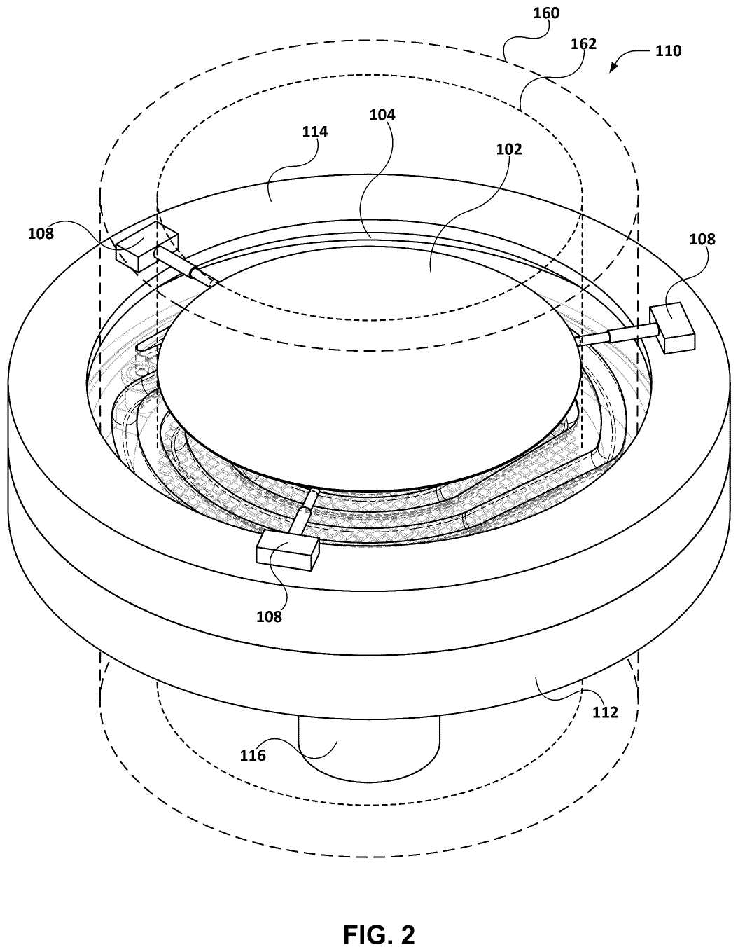

FIG. 2 depicts the same pedestal 110 as in FIG. 1, but with a wafer 102 being supported by the wafer supports 108 over the window 104. As can be seen, the wafer 102 is suspended over the window 104 and is supported only by the contact surfaces 188. The wafer 102 thus has minimal thermally conductive contact. When the pedestal 110 and the wafer 102 are thus in a vacuum environment in which convective heat conduction is similarly constrained, the illumination sources 124 may be used to radiatively heat the wafer 102 to a desired temperature, e.g., up to 400° C.

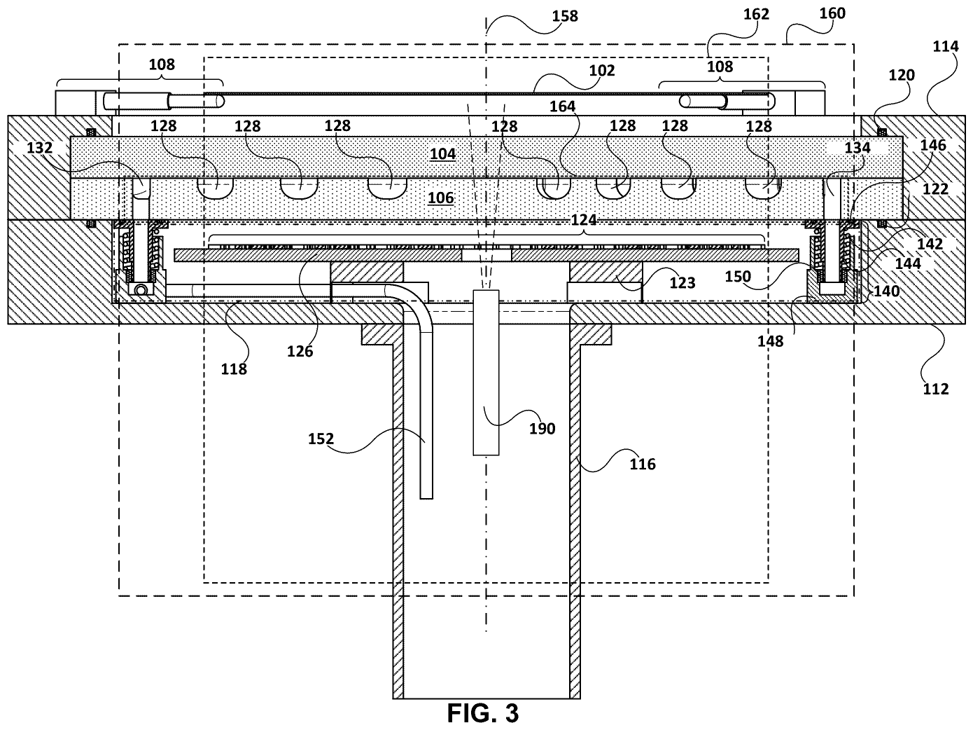

FIG. 3 depicts a section view of the pedestal 110 of FIG. 2 (with the wafer 102 in place). As can be seen more clearly in this view, the window 104 in this example is a generally circular, flat disk that is bonded, e.g., via an optically clear adhesive or through diffusion bonding, to the cooling plate 106. The cooling plate 106 in this example has cooling passage 128, e.g., an open channel in a side of the cooling plate 106 facing the window 104, winding across it. In some implementations, there may be more than one cooling passage 128, e.g., multiple cooling passages 128 following parallel paths. The cooling passage(s) 128 may have one or more portions that are distributed throughout an annular or cylindrical sub-portion 164 of the first cylindrical zone 160. A first end of the cooling passage or passages 128 may be fluidically connected with an inlet 132 and a second end of the cooling passage or passages 128 may be fluidically connected with an outlet 134 such that the one or more cooling passages 128 are each fluidically interposed between the inlet 132 and the outlet 134 (or between corresponding inlets and outlets).

The window 104 and the cooling plate 106 may be clamped against a lower seal 122 in the pedestal housing 112 and an upper seal 120 in the collar 114 such that an internal cavity 118 of the pedestal housing 112 is closed off by the window 104 and the cooling plate 106. The internal cavity 118 may house within it a printed circuit board (PCB) or boards 126 that may support a large number of illumination devices 124, e.g., several hundred illumination devices 124 or on the order of a thousand or several thousand illumination devices 124, e.g., 1500 or more illumination devices 124, within the first cylindrical zone 160. The PCB 126 may be supported within the internal cavity 118 by a support 123.

The inlet 132 and the outlet 134 may each be coupled to a corresponding fluidic interface 140. Each fluidic interface 140, for example, may include a floating flange 144 that has a flange plate housing a flange seal 146 and a tubular stem segment that extends downward into a stem seal 150 in a flange base 148. A spring 142 may be sandwiched between the flange base 148 and the flange of the floating flange 144 such that when the floating flange 144 pressed downward towards the flange base 148, the spring 142 pushes the floating flange 144 upwards. Such a fluidic interface 140 may thus provide a liquid-tight seal interface against the underside of the cooling plate 106 that is able to adapt to slight changes in position of the cooling plate 106 and/or the window 104 due to, for example, temperature expansion effects. Such an arrangement may also provide a light-tight seal that avoids the need for a threaded coupling or any nominally cylindrical surface-to-surface contact between the cooling plate 106 and a fluidic coupling. This prevents potential thermal expansion issues that may arise with such couplings, e.g., mismatched thermal expansion between the inlet 134 and a metal coupling inserted therein, that may cause cracks to develop in the cooling plate 106.

Each fluidic interface 140 may be fluidically connected with corresponding tubing 152 (only one piece of tubing 152 is shown, but it will be understood that a similar piece of tubing may be connected with the other fluidic interface 140 as well) that may be routed down the stem 116 to, for example, a coolant reservoir and/or pump. The stem 116 may also, in some implementations, house an optical sensor 190. The optical sensor 190 may be configured to obtain measurements, e.g., of one or more of temperature, transmissivity, reflectance, etc, from the wafer 102 (which is supported by the wafer supports 108) through the cooling plate 106 and the window 104. The optical sensor 190 may, for example, be a pyrometer or other optically-based remote-sensing device.

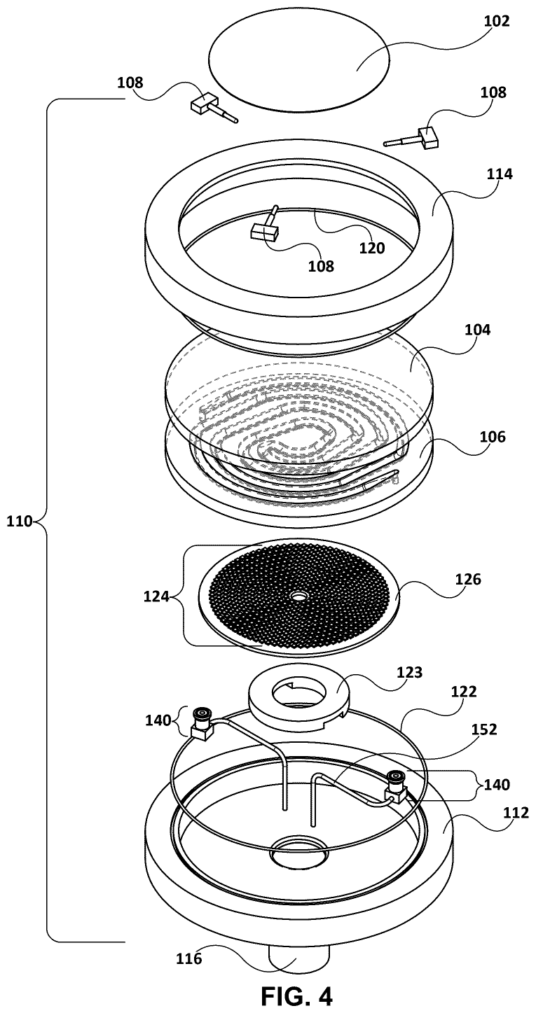

FIG. 4 depicts an exploded view of the pedestal 110 with the wafer 102. The two fluidic interfaces 140 are more clearly visible in this view, along with the PCB 126 with the illumination devices 124.

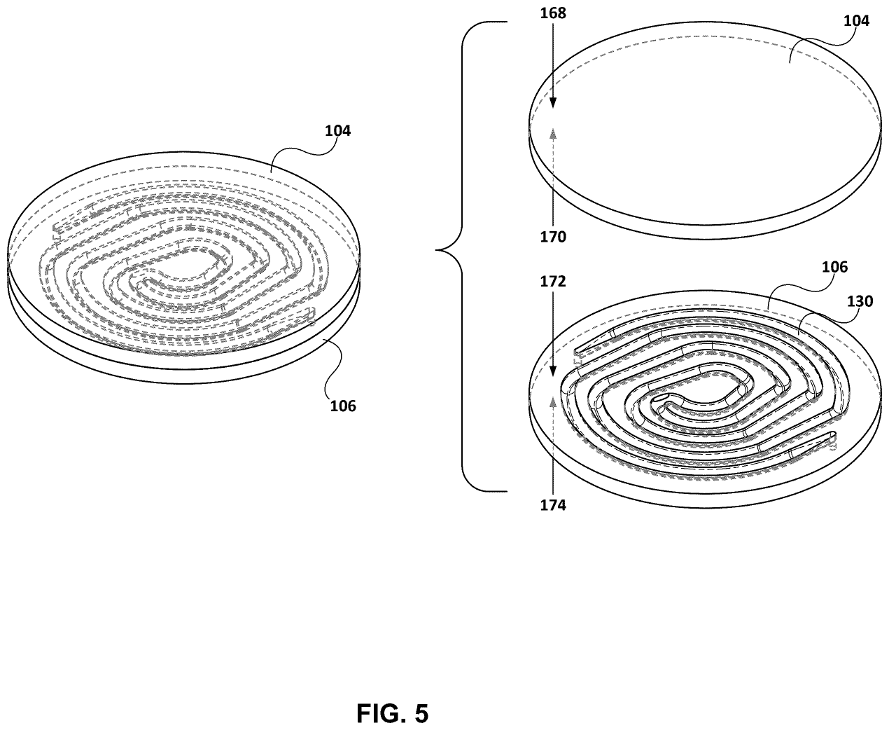

FIG. 5 depicts a view of the window 104/cooling plate 106 assembly on the left, and the same assembly in an exploded view on the right. As can be seen, the window 104 may have a first surface 168 (which faces towards the wafer 102 when the pedestal 110 is used to support the wafer 102) and a second surface 170 that faces in the opposite direction from the first surface 168. The cooling plate 106 may similarly have a third surface 172 that faces towards, and is adjacent to (when the window 104 and cooling plate 106 are assembled) the second surface 170. The cooling plate may also have a fourth surface 174 that faces away from the third surface 172. In this example, the third surface 172 of the cooling plate 106 has an open channel 130 in it that provides the cooling passage 128. When the window 104 is sealed to the cooling plate 106, e.g., via adhesive or diffusion bonding, the open channel 130 may be capped off by the window 104, thereby enclosing the cooling passage 128. It will be understood that the first, second, etc., surfaces discussed herein with reference to the window 104 and cooling plate 106 (or similar structures) may be generally planar surfaces, sometimes with a channel or channels recessed into them. Reference to a feature being interposed between two surfaces will be understood to mean that such a feature is either between those two surfaces or between planes coincident with, and parallel to, such surfaces.

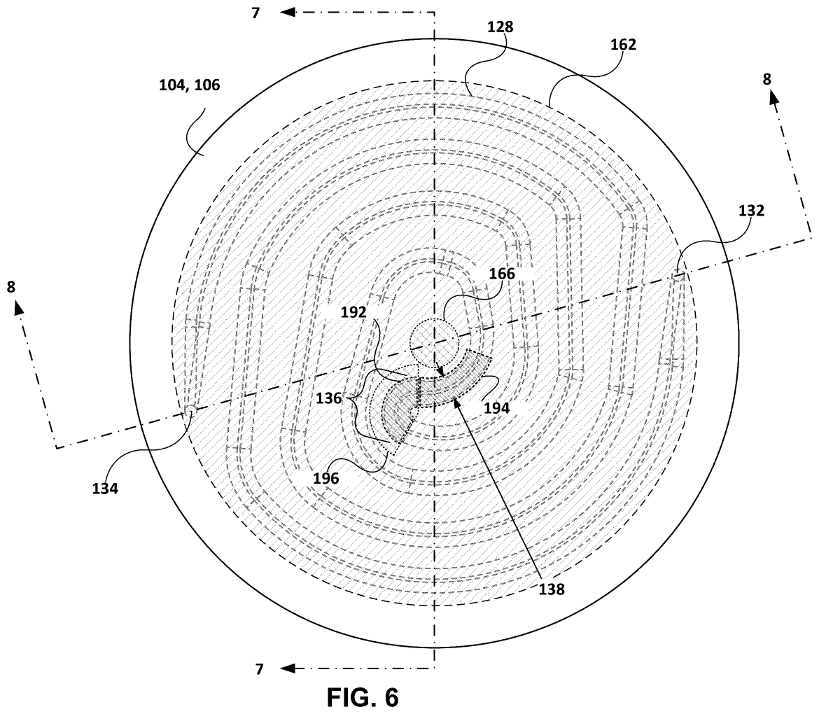

FIG. 6 depicts a plan view of the window 104/cooling plate 106 assembly. As can be seen, the cooling passage 128 has two portions that each spiral inwards from the inlet 132 and the outlet 134, respectively, in a generally nested manner within the first cylindrical zone 162. For example, each portion may generally follow the same path as the other for one or more spiral revolutions, but rotated by 180° from the other portion about the center axis 158 (not shown, but passing through the center of the cooling plate 106 and perpendicular to the page). Thus, the two portions may include a first portion that is fluidically interposed between the inlet 132 and a second portion. The second portion may similarly be fluidically interposed between the first portion and the outlet 134.

In the depicted example, the cooling passage 128 is configured so as to not cross into a cylindrical center zone 166 of the window 104/cooling plate 106. The cylindrical center zone 166 may, for example, provide a line-of-sight from the optical sensor 190 to the wafer 102 that only passes through the window 104 and optionally the cooling plate 106 but which does not pass through the cooling passage 128. This prevents the optical sensor 190 readings from being affected by passing through the coolant circulated through the cooling passage 128. In some implementations, the cooling plate 106 may have a blind or through-hole in it that is coextensive with, or overlaps with, the center cylindrical zone 166. This may reduce the amount of material that the optical sensor 190 would need to take a reading through and may result in more accurate readings, e.g., of temperature. It may also reduce the risk of condensation collecting on the underside of the cooling plate.

In some implementations, the cylindrical center zone 166 may have a radius large enough to allow a line-of-sight measurement of the wafer 102 to be obtained by the optical sensor 190, e.g., at least 5 mm, without needing to pass through the cooling plate 106. In some such implementations, the cylindrical center zone 166 may also be small enough, e.g., less than about 15 mm, that the cooling passage(s) 128 are able to traverse across most of the first cylindrical zone 160 without significant gaps in cooling passage coverage. However, in other implementations, the center cylindrical zone 166 may be sized to have a radius of at least 75 mm, thereby constraining the cooling passage 128 to traverse through a generally annular region, e.g., so as to only directly cool an outer annular region of the window 104 and the cooling plate 106. Such an implementation may be less costly to manufacture due to the reduced length of the cooling passage(s) required, but may still provide adequate cooling in some circumstances.

In general, the cooling passage 128 may be designed to provide for a smooth flow path with larger radius bends, e.g., bends having a centerline radius of 1.5 times the passage width or higher, to avoid the potential for flow separation, which may occur in areas where fluid flow undergoes a sudden and significant change in direction that causes a sudden decrease in flow velocity. If flow separation occurs, there is an increased likelihood of bubbles becoming trapped in the region in which the flow separation manifests. In order to avoid such a potential, portions of the cooling passage 128 that are immediately downstream of an area with a sudden change in fluid flow direction, such as a small-radius U-turn, may be designed so as to have a somewhat smaller cross-section, e.g., by decreasing the width of the cooling passage 128.

For example, if the cooling passage 128 has a first segment 192 that lies entirely within a circular sector zone 196 having an angle of 150° or more and an outer radius that is less than twice the cross-sectional width of the cooling passage, and that first segment 192 enters and exits the circular sector zone 196 along radii of the circular sector zone, e.g., as shown in FIG. 6, such a first segment 192 may be a small-enough radius turn 136 that there will be an increased risk of flow separation in a second segment 194 of the cooling passage 128 that is immediately downstream of the first segment 192 (put another way, the second segment 194 may be fluidically interposed between the first segment 192 and the outlet 134) and of the same flow path length as the first segment 192 due to the decreased flow velocity of the coolant upon exiting that turn 136. Accordingly, the width (or, more generally, the cross-sectional area) of the cooling passage 128 at one or more locations in the second segment 194 may be reduced compared to the average width (or, more generally, cross-sectional area) of the cooling passage 128 in the first segment 192. For example, the minimum cross-sectional area of the second segment 194 may be smaller than the average cross-sectional area of the first segment 192. In some implementations, the minimum cross-sectional area of the second segment 194 may be at least 10% smaller than the average cross-sectional area of the first segment 192.

In the depicted example, the width (and cross-sectional area) of the cooling passage 128 stays constant except in the second segment 194 (and continuing on downstream in the cooling passage 128 for one or two more segments of similar length thereto) and in the tapering sections adjacent the inlet 132 and the outlet 134. Incorporating such a reduced cross-sectional area may allow the flow path followed by such a cooling passage 128 to undergo a sharp, 180° turn, thereby allowing a flow path as shown to have portions that are nearly identical but rotated 180° from one another about a center axis (not shown, but at the center of the cooling plate 106) and which are then joined by a small-radius, sharp turn, as shown in FIG. 6. This arrangement may provide for relatively even cooling of the window 104 while avoiding the generation or entrapment of bubbles within the coolant flow.

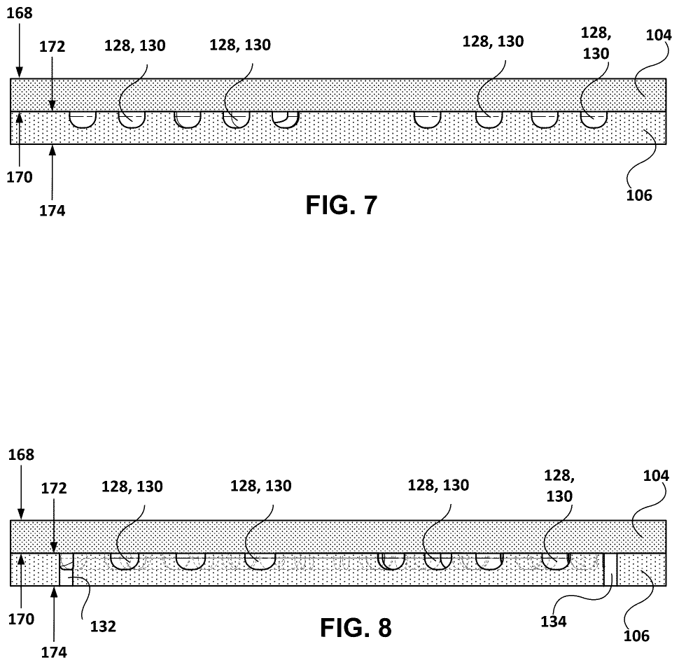

It will be understood that the window 104 and the cooling plate 106 may be implemented in a number of ways, although in all such implementations, the cooling passage(s) may be located between the first surface 168 of the window 104 and the fourth surface 174 of the cooling plate 106. For example, FIGS. 7 and 8 depict cross-sections through the section lines shown in FIG. 6. As noted earlier, the first surface 168 of the window 104 may face upward towards the wafer 102, and the second surface 170 of the window 104 may be adjacent to, and bonded to, the third surface 172 of the cooling plate 106. As noted earlier, in the depicted example, the cooling passage 128 is provided by an open channel 130 in the cooling plate 106 that is capped by the window 104.

Such an arrangement allows the window 104 to be a simple geometric solid, e.g., a flat disk or cylinder. In the case where the window 104 is a material such as monocrystalline sapphire, AlON™, Spinel™, or monocrystalline calcium fluoride (CaF), this may help keep the cost of the window 104 relatively low, as the window may have a simple geometry with no holes, channels, or other recessed features requiring drilling, milling, or other similar processes that may be extremely costly to perform on a hard, brittle material and that may then be difficult to polish to achieve a desired degree of optical clarity. The cooling plate 106 in such a configuration may be made of, for example, quartz, glass, borosilicate glass (such as Pyrex™), which may be (relatively) much more machinable, thereby allowing the cooling passage 128 to be produced in a cost-effective manner. The cooling plate 106 may, for example, be made of materials having optical properties as discussed above that are otherwise suitable for use in the contexts described. Transparent polymeric materials, for example, would generally not be suitable for use in such contexts since the cooling plate 106 may reach temperatures of up to 100° C. However, many silicon-based transparent materials may be suitable, in addition to the other materials, such as sapphire, discussed earlier herein.

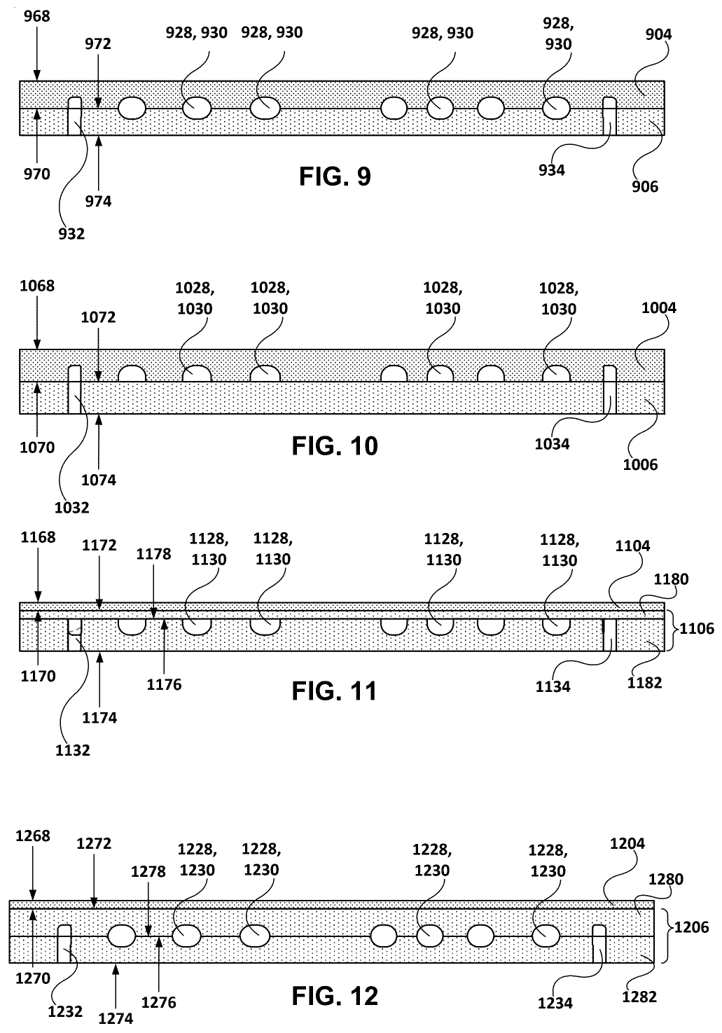

FIG. 9 depicts an alternate implementation of a window 904 and a cooling plate 906. Similar to the window 104 and the cooling plate 106, the window 904 has a first surface 968 and a second surface 970, while the cooling plate 906 has a third surface 972 and a fourth surface 974. Matching open channels 930 may be machined or formed in the second surface 970 of the window 904 and the third surface 972 of the cooling plate 906 such that when the second surface 970 is bonded to the third surface 972, the open channels 930 may align to form the cooling passage 928. The cooling passage 928 may, for example, be fluidically interposed between the inlet 932 and the outlet 934. Such an arrangement may be difficult to machine due to the need to cut or form the open channels 930 in the second surface 970, although still technically feasible.

FIG. 10 depicts another alternate implementation of a window 1004 and a cooling plate 1006. Similar to the window 104 and the cooling plate 106, the window 1004 has a first surface 1068 and a second surface 1070, while the cooling plate 1006 has a third surface 1072 and a fourth surface 1074. Open channel 1030 may be machined or formed in the second surface 1070 of the window 1004 such that when the second surface 1070 is bonded to the third surface 1072, the open channel 1030 is capped by the cooling plate 1006 to form the cooling passage 1028. The cooling passage 1028 may, for example, be fluidically interposed between the inlet 1032 and the outlet 1034. Such an arrangement may, as with that of FIG. 9, be difficult to machine due to the need to cut or form the open channels 1030 in the second surface 1070, although still technically feasible.

FIG. 11 depicts another alternate implementation of a window 1104 and a cooling plate 1106. Similar to the window 104 and the cooling plate 106, the window 1104 has a first surface 1168 and a second surface 1170, while the cooling plate 1106 has a third surface 1172 and a fourth surface 1174. The cooling plate 1106 in this example is formed of two portions—a first portion 1180 and a second portion 1182 that may be bonded to the first portion 1180. The first portion 1180 may include the third surface 1172 and a fifth surface 1176, while the second portion 1182 may include the fourth surface 1174 and a sixth surface 1178. An open channel 1130 may be machined or formed in the sixth surface 1178 of the second portion 1182 of the cooling plate 1106 such that when the fifth surface 1176 of the first portion 1180 is bonded to the sixth surface 1178 of the second portion 1182, the open channel 1130 is capped by the fifth surface 1176 to form the cooling channel 1128. The cooling passage 1128 may, for example, be fluidically interposed between the inlet 1132 and the outlet 1134. Such an arrangement may allow the cooling plate 1106 to be placed adjacent to the window 1104 without needing to bond the cooling plate 1106 to the window 1104 to cap the open channel 1130. In such an implementation, the window 1104 may be interfaced to the cooling plate 1106 using an optically clear thermally conductive compound or other non-adhesive heat transfer medium. This may allow, for example, the cooling plate 1106 to be removed from the window 1104, e.g., for replacement, without also needing to replace the window 1104. At the same time, the window 1104 may be a simple geometric solid, e.g., as with the window 104.

FIG. 12 depicts another alternate implementation of a window 1204 and a cooling plate 1206. Similar to the window 1104 and the cooling plate 1106, the window 1204 has a first surface 1268 and a second surface 1270, while the cooling plate 1206 has a third surface 1272 and a fourth surface 1274. The cooling plate 1206 in this example, like the cooling plate 1106, is formed of two portions—a first portion 1280 and a second portion 1282 that may be bonded to the first portion 1280. The first portion 1280 may include the third surface 1272 and a fifth surface 1276, while the second portion 1282 may include the fourth surface 1274 and a sixth surface 1278. Open channels 1230 may be machined or formed in the fifth surface 1276 of the first portion 1280 and the sixth surface 1278 of the second portion 1282 of the cooling plate 1206 such that when the fifth surface 1276 of the first portion 1280 is bonded to the sixth surface 1278 of the second portion 1282, the open channels 1230 may be aligned to form the cooling passage 1228. The cooling passage 1228 may, for example, be fluidically interposed between the inlet 1232 and the outlet 1234. As with the cooling plate 1106, such an arrangement may allow the cooling plate 1206 to be placed adjacent to the window 1204 without needing to bond the cooling plate 1206 to the window 1204 to cap the open channels 1230 with each other. In such an implementation, as with the implementation of FIG. 11, the window 1204 may be interfaced to the cooling plate 1206 using an optically clear thermally conductive compound or other non-adhesive heat transfer medium. This may allow, for example, the cooling plate 1206 to be removed from the window 1204, e.g., for replacement, without also needing to replace the window 1204. At the same time, the window 1204 may be a simple geometric solid, e.g., as with the window 104.

It will also be noted that the implementations of FIGS. 9 and 12 have cooling passages 928 and 1228 that have cross-sections that are, along most or all of their lengths, devoid of sharp interior corners, e.g., cross-sections that are round, ovoid, obround, or otherwise rounded and lacking sharp corners. Such cooling passages may reduce the chance of stagnant flow regions developing within the cooling passage. Such stagnant flow regions may, for example, have a higher risk of potentially trapping bubbles and may thus tend to collect any bubbles that may flow through the cooling passage 928 or 1228. By having a cooling passage 928 or 1228 that features no sharp interior corners, it may be possible to mitigate or eliminate this risk, thereby reducing the chance of bubbles getting stuck within the cooling passage 128.

The cooling passages 128, 1028, and 1128 also feature cross-sections with some non-sharp interior corners, but such cross-sections also feature some sharp interior corners, e.g., at the interfaces between the windows 104/1004/1104 and the cooling plates 106/1006/1106. The rounded interior corners in such cooling passages 128, 1028, and 1128 may similarly act to discourage bubble entrapment in the portions of the cooling passages 128, 1028, and 1128 having the rounded interior corners, although the sharp interior corners that are still present in other portions of the cooling passages 128, 1028, and 1128 may still present an increased risk of bubble entrapment.

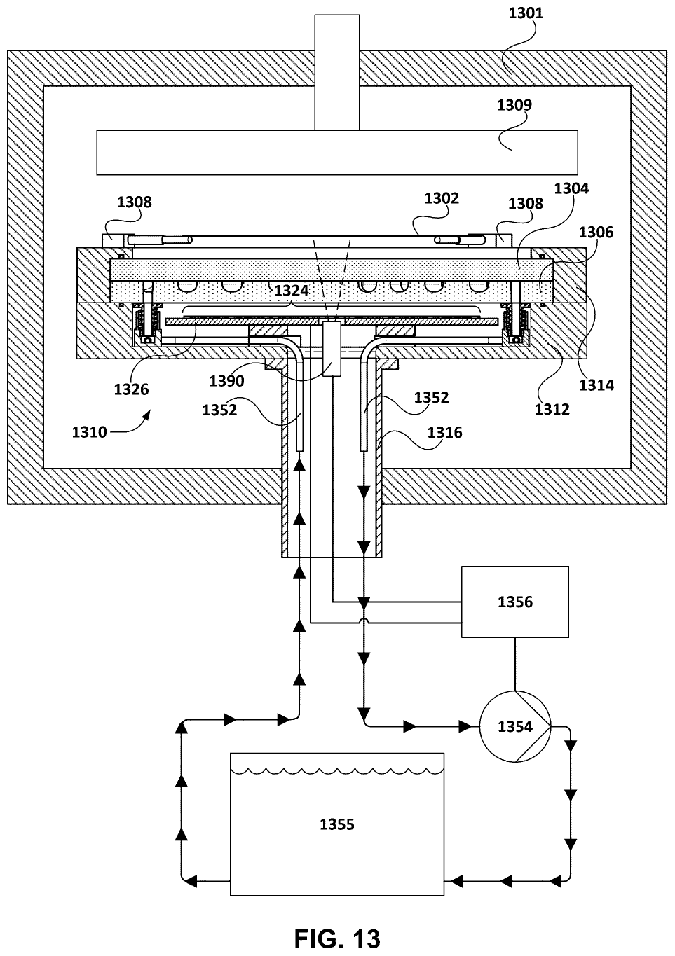

FIG. 13 depicts a schematic of a semiconductor processing chamber in which a pedestal such as the pedestals discussed herein may be used. As shown in FIG. 13, a semiconductor processing chamber 1301 is depicted that houses a showerhead 1309 that is suspended over a pedestal 1310. The showerhead 1309 may be configured to flow one or more processing gases, e.g., hydrogen fluoride-containing gases, over a wafer 1302 that may be supported relative to the pedestal 1310 by way of wafer supports 1308.

The pedestal 1310 may include a pedestal housing 1312 that is supported by a stem 1316. The pedestal housing 1312 may have an internal cavity that is closed off by a cooling plate 1306 and a window 1304. The internal cavity may house a PCB 1326 that supports a plurality of illumination devices 1324 that are oriented to illuminate the underside of a wafer 1302. The pedestal 1310 may also include a collar 1314 that may, for example, support the wafer supports 1308 and that may be used to secure the window 1304 and the cooling plate 1306 in place relative to the pedestal housing 1312.

The internal cavity of the pedestal 1310 may be sealed off from the interior of the semiconductor processing chamber 1301 such that the internal cavity of the pedestal 1310 may be kept at, for example, atmospheric pressure while the interior of the semiconductor processing chamber 1301 is kept at vacuum or near-vacuum conditions. The stem 1316 may thus serve as a conduit through which various cables, hoses/tubing/etc. may be passed to reach equipment located within the pedestal 1310. For example, the pedestal 1310 may include tubes 1352 that may connect with an inlet and an outlet of the cooling plate 1306, e.g., via fluidic interfaces, to allow coolant from a coolant reservoir 1355 to be drawn into the cooling passage(s) of the cooling plate 1306/window 1304 by operation of a pump 1354. Such coolant may be any suitably clear liquid with suitable heat transfer characteristics, for example, water, deionized water, distilled water, etc. The pump 1354, it will be noted, may be configured to only apply suction to the cooling passage, thereby causing suction to be generated at the inlet to the cooling passage. Such suction may draw the coolant liquid from the coolant reservoir 1355 and through the coolant passage, thereby avoiding potentially pressurizing the cooling passage. At the same time, the outlet of the pump 1354 may not be connected with the inlet in a way that would result in the pump 1354 being able to apply positive pressure to the cooling passage. This avoids the risk of having the pressure differential across the window 1304 potentially increase to the point where the window 1304 may be vulnerable to failure. The stem 1316 may also house an optical sensor 1390 that may be configured to obtain sensor readings, e.g., temperature readings, from the underside of the wafer 1302 through the window 1304. A controller 1356 may be provided to provide control signals to the pump 1354 and/or the optical sensor 1390, for example, to cause the pump 1354 to pump coolant and/or the optical sensor 1390 to obtain sensor readings.

The systems discussed above may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including wafer heating, coolant flow, optical measurement, etc.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that stores program instructions, digital signal processors (DSPs), chips defined as application-specific integrated circuits (ASICs), and/or one or more microprocessors, or microcontrollers that execute program instructions (e.g., software). Program instructions may be instructions communicated to the controller in the form of various individual settings (or program files), defining operational parameters for operating the illumination devices within the pedestal and/or controlling the flow of coolant through the cooling passage(s).

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control the operation of a pedestal with illumination-based heating.

Without limitation, example systems that may include the apparatuses discussed herein may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
a window having a first surface and a second surface, wherein the first surface is non-reactive with hydrogen fluoride;
a cooling plate having a third surface and a fourth surface, wherein:
the window and cooling plate are both transparent to at least some light in the 400 nm to 800 nm spectrum within at least a first cylindrical zone having a center axis perpendicular to the first surface,
the third surface is adjacent to the second surface; and
one or more cooling passages interposed between the first surface and the fourth surface, wherein the one or more cooling passages are at least partially within the first cylindrical zone.

2. The apparatus of claim 1, wherein the third surface is bonded to the second surface.

3. The apparatus of claim 1, wherein at least one of the one or more cooling passages is provided, at least in part, by an open channel in the third surface that is capped by the second surface.

4. The apparatus of claim 1, wherein at least one of the one or more cooling passages is provided, at least in part, by an open channel in the second surface that is capped by the third surface.

5. The apparatus of claim 1, wherein at least one of the one or more cooling passages is located between the fourth surface and the second surface.

6. The apparatus of claim 5, wherein:
the cooling plate includes a first portion and a second portion,
the first portion includes the third surface and a fifth surface,
the second portion includes the fourth surface and a sixth surface,
the fifth surface is bonded to the sixth surface, and
each of the one or more cooling passages is an open channel in one or both of the fifth surface and the sixth surface.

7. The apparatus of claim 1, wherein portions of at least a first cooling passage of the one or more cooling passages are distributed throughout at least an annular sub-portion of the first cylindrical zone.

8. The apparatus of claim 7, wherein:
at least the first cooling passage of the one or more cooling passages includes a first segment that lies entirely within a circular sector zone and that extends from one radial edge of the circular sector zone to another radial edge of the circular sector zone,
the circular sector zone has an angle of at least 1500 and an outer radius less than twice the average width of the first cooling passage within the circular sector zone,
the first cooling passage has a second segment of equal or lesser length than the first segment,
the first segment transitions to the second segment, and
at least one of the first segment and the second segment has a minimum cross-sectional area that is smaller than an average cross-sectional area of the first segment.

9. The apparatus of claim 8, wherein:
the minimum cross-sectional area is in the second segment and is fluidically interposed between the first segment and a first outlet of the first cooling passage,
the first cooling passage leads from a first inlet to the first outlet,
a first portion of the first cooling passage is fluidically interposed between the first inlet and a second portion of the first cooling passage,
the second portion of the first cooling passage is fluidically interposed between the first portion of the first cooling passage and the first outlet, and
the first portion of the first cooling passage and the second portion of the first cooling passage follow nested, generally spiral-shaped paths.

10. The apparatus of claim 7, wherein:
the first cooling passage leads from a first inlet to a first outlet,
a first portion of the first cooling passage is fluidically interposed between the first inlet and a second portion of the first cooling passage,
the second portion of the first cooling passage is fluidically interposed between the first portion of the first cooling passage and the first outlet, and
the first portion of the first cooling passage and the second portion of the first cooling passage follow nested, generally spiral-shaped paths.

11. The apparatus of claim 10, further comprising a pump having a pump inlet and a pump outlet, wherein:
the pump inlet is fluidically connected with the first outlet such that suction developed at the pump inlet also generates suction at the first inlet, and
the pump outlet is not connected with the first inlet so that positive pressure developed at the pump outlet is not communicated to the first inlet.

12. The apparatus of claim 1, wherein the one or more cooling passages do not pass through a cylindrical center zone centered on the center axis and extending through the window and the cooling plate.

13. The apparatus of claim 12, wherein the cooling plate has a hole in it within the cylindrical center zone.

14. The apparatus of claim 12, further comprising an optical sensor configured to obtain temperature measurements through the window and the cooling plate and within the cylindrical center zone.

15. The apparatus of claim 1, further comprising:
a plurality of illumination devices located within the first cylindrical zone and positioned so as to emit light, responsive to being powered, through the cooling plate and the window.

16. The apparatus of claim 15, further comprising a pedestal housing, wherein:
the pedestal housing includes an internal cavity,
the window is installed in the pedestal housing so as to close off the internal cavity, and
the illumination devices are located within the internal cavity.

17. The apparatus of claim 16, further comprising a plurality of wafer supports, wherein:
each wafer support has a first portion that lies within a second cylindrical zone and a second portion that lies outside of the second cylindrical zone,
the first portion of each wafer support has a wafer contact surface that is spaced apart from the first surface by a first distance,
the first distance is a non-zero distance, and
the second portion of each wafer support supports the first portion of that wafer support relative to the pedestal housing.

18. The apparatus of claim 1, further comprising a pump having a pump inlet and a pump outlet, wherein:
at least a first cooling passage of the one or more cooling passages has a first inlet and a first outlet, with the first cooling passage fluidically interposed between the first inlet and the first outlet,
the pump inlet is fluidically connected with the first outlet such that suction developed at the pump inlet also generates suction at the first inlet, and
the pump outlet is not connected with the first inlet so that positive pressure developed at the pump outlet is not communicated to the first inlet.

19. The apparatus of claim 1, wherein the window and cooling plate are both at least 80% transmissive to at least some light in the 400 nm to 800 nm wavelength spectrum to a depth of at least 2 mm within at least the first cylindrical zone.

20. The apparatus of claim 19, wherein the window and cooling plate are both at least 80% transmissive to all light in the 400 nm to 800 nm wavelength spectrum to a depth of at least 2 mm within at least the first cylindrical zone.
